(19) United States
(12) Patent Application Publication
(10) Pub. No.: US 2005/0074923 A1
(43) Pub. Date: Apr. 7, 2005

(54) Metallic dam and method of forming therefor

(76) Inventor: Vahid Goudarzi, Coral Springs, FL (US)

Correspondence Address: AKERMAN SENTERFITT, P.O. BOX 3188, WEST PALM BEACH, FL, 33402-3188, US

(21) Appl. No.: 10/678,834

(22) Filed: Oct. 3, 2003

(51) Int. Cl. H01L 21/50; H01L 21/44; H01L 21/48; H01L 21/4763

(52) U.S. Cl. 438/119; 438/121; 438/106

(57) ABSTRACT

A processed printed circuit board (50 or 80) can include a predetermined area on a substrate (40) defined by a metallized trace pattern (26) and solder (32 or 62) applied to the metallized trace pattern to form a dam around the predetermined area. The board can further include an optional electronic component (22) such as a semiconductor die within the predetermined area along with a conformal coating (52 or 82) applied to the predetermined area. A conformal coating (95) can also be applied to a predetermined area where no components lie underneath.

### CROSS-REFERENCE TO RELATED APPLICATIONS

Not applicable.

### FIELD OF THE INVENTION

This invention relates in general to the application of metals to substrates, and more particularly to forming dams from metals such as solder.

### BACKGROUND OF THE INVENTION

Dams on printed circuit boards are required for over molding or glob-top operations to prevent overflow of over mold materials onto different components. Over mold materials are used to protect semiconductor dies on a flip chip or to protect both a wire bond and die on the wire-bonded dies.

Currently dams are made using two different processes. These processes include dispensing or printing epoxy. Unfortunately, either epoxy process introduces relatively large clearance requirements between the wire bond pads or die to the components placed around the die. Such large clearance requirements require sufficient spacing to prevent the dam from interfering with an adjacent component or to cover the pads for different components such as shields. The clearance requirements can be up to 47 mils which result in an increase in the overall module size. Further note that using epoxy as described above introduces an unnecessary additional step in processing a printed circuit board with components as will be become apparent in the detailed description below. Referring to FIG. I, a printed circuit board 10 illustrates that in some arrangements, there fails to be sufficient space in insufficient clearance areas 12 between the wire bond pads and the adjacent components as well as between the wire bond pads and shield tracks. Meeting the design guideline using existing dam techniques will increase the overall module size.

### SUMMARY OF THE INVENTION

Embodiments in accordance with the invention illustrate an apparatus and methods to create dams with minimum clearance requirements. In addition, this method can eliminate the need for dispensing or printing the dam as a separate step in populating a circuit board with components. In a first aspect of the present invention, a method of forming a metallized dam can include the steps of applying a metallic adhesive to a printed circuit board having at least one dam pattern thereon and the step of applying a conformal coating about a dam formed around the at least one dam pattern. The dam pattern can be created during the manufacture of the printed circuit board. In other words, the dam pattern can be a part of the art work for the printed circuit board. The dam pattern can also be electrically non-functional. The metallic adhesive can be solder such as solder paste or solder preforms. The step of applying the metallic adhesive can include reflowing the solder paste or the solder preforms on to the at least one dam pattern. The method can also include the steps of placing a semiconductor die within the dam and wire bonding the semiconductor die to bonding pads within the dam before the step of applying the conformal coating. Note that the application of solder paste or even preforms can be adjusted to provide a customized height for the dam.

In a second aspect of the present invention, a method of forming a dam can include the steps of circumscribing a predetermined area on a substrate with a metallized trace pattern, applying solder such as solder paste or solder preforms to the metallized trace pattern, and reflowing the solder to form the dam using the solder. The method can further include the steps of optionally placing a component such as a semiconductor die within the dam and applying a conformal coating about the dam. Note that the step of placing the component can occur either before or after the step of reflowing.

In a third aspect of the present invention, a processed printed circuit board can include a predetermined area on a substrate defined by a metallized trace pattern and solder applied to the metallized trace pattern to form a dam around the predetermined area. The board can further include an optional electronic component such as a semiconductor die within the predetermined area along with a conformal coating applied to the predetermined area. A conformal coating can also be applied to a predetermined area where no components lie underneath.

### BRIEF DESCRIPTION OF THE DRAWINGS

FIG. 1 shows a top view of a printed circuit board layout that has insufficient clearance in noted area using conventional epoxy dams that can benefit from use of the present invention.

FIG. 2 shows a top view of a printed circuit board portion illustrating a metallic trace circumscribing a component to form a dam pattern in accordance with the present invention.

FIG. 3 shows a top view of the printed circuit board portion of FIG. 2, further illustrating solder preform on top of the dam pattern in accordance with the present invention.

FIG. 4 shows a side view of a portion of the printed circuit board of FIG. 3 before reflowing.

FIG. 5 shows a side view of a portion of the printed circuit board of FIG. 3 after reflowing to create the dam for retaining a conformal coating in accordance with the present invention.

FIG. 6 shows a top view of the printed circuit board portion of FIG. 2, further illustrating solder paste on top of the dam pattern in accordance with the present invention.

FIG. 7 shows a side view of a portion of the printed circuit board of FIG. 6 before reflowing.

FIG. 8 shows a side view of a portion of the printed circuit board of FIG. 6 after reflowing to create the dam for retaining a conformal coating in accordance with the present invention.

FIG. 9 shows a top view of a flexible circuit having an aperture that has a metallic trace circumscribing such aperture to form a dam pattern in accordance with the present invention.

FIG. 10 shows a top view of the printed circuit board portion of FIG. 9, further illustrating solder on top of the dam pattern and a conformal coating about the dam pattern in accordance with the present invention.

FIG. 11 is a flow chart illustrating a method of forming a metallized dam in accordance with the present invention.

FIG. 12 is a flow chart illustrating another method of forming a metallized dam in accordance with the present invention.

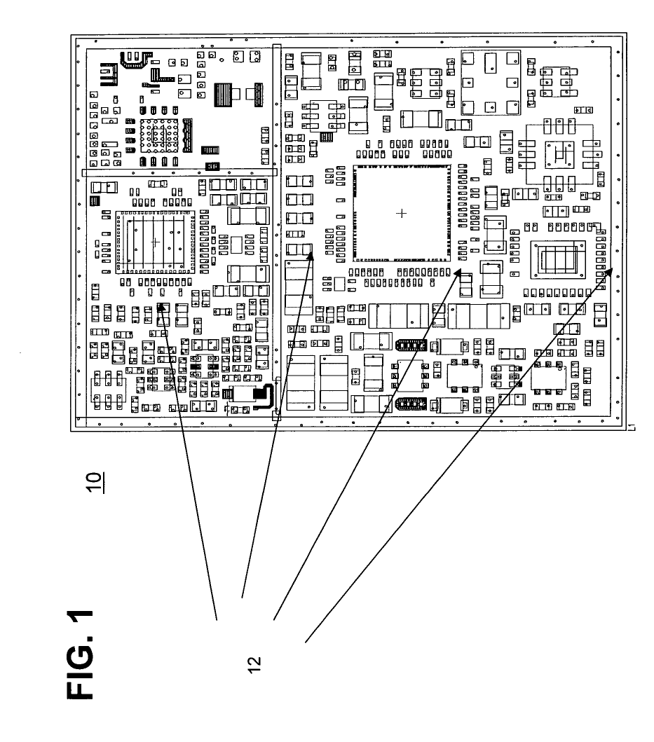

### DETAILED DESCRIPTION OF THE DRAWINGS

While the specification concludes with claims defining the features of the invention that are regarded as novel, it is believed that the invention will be better understood from a consideration of the following description in conjunction with the drawing figures, in which like reference numerals are carried forward.

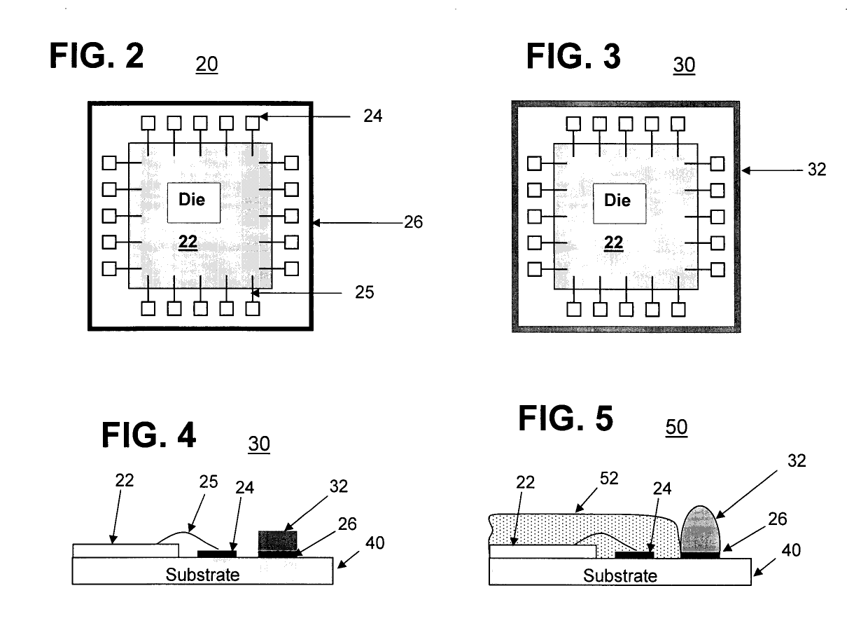

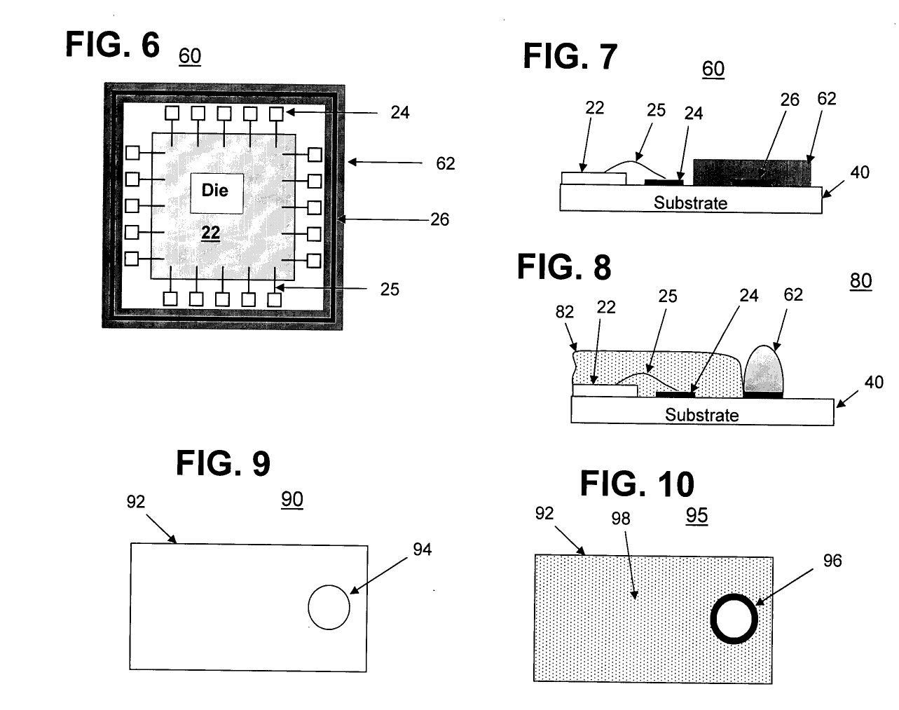

Referring now to FIGS. 2-8, a processed printed circuit board 20 can include a predetermined area on a substrate defined by a metallized trace pattern 26. The trace pattern can preferably be created during the printed circuit board (PCB) manufacturing process. Thus, a preprinted PCB would include a “dam pattern” ready for solder application during a normal solder screen printing operation, for example. In this manner, a separate step (as done in forming existing epoxy dams) for forming a dam is eliminated. A partially processed PCB 30 or 60 (a pre-printed PCB having solder) can further include solder in the form of a solder preform 32 (as shown in FIGS. 3 and 4) or in the form of solder paste 62 (as shown in FIGS. 6 and 7) applied to the metallized trace pattern 26 to form a dam around the predetermined area. As an example, solder paste can be placed on the trace pattern 26 using screen printing process. The board can further include an optional electronic component 22 such as a semiconductor die within the predetermined area. The semiconductor die can use direct chip-attach or flip chip techniques (not shown) or can alternatively use wire bonding 25 to wire bond pads 24 on the periphery of the semiconductor die for providing suitable operational coupling. Before reflowing, the solder 32 or 62 lies on top of a metallized trace pattern 26 on top of a substrate 40 as shown in FIGS. 4 or 7. Once the solder 32 or 62 is reflowed as shown in FIGS. 5 and 8, a dam is created on top of the dam pattern or trace pattern 26. Note that the dam pattern can be electrically non-functional and serve no other purpose except a mechanical function. Optionally, the dam pattern can also serve an electrical function (e.g., ground) if so desired. The height of the dam can be adjusted by over-printing the solder paste or applying predetermined amounts of solder preforms accordingly. More solder paste or more solder preforms will naturally cause the solder to bead-up higher. Once the dam is formed as shown in FIGS. 5 and 8, a conformal coating 52 or 82 respectively (such as over-mold or glob-top) can be applied to the predetermined area.

Referring to FIG. 9, a flexible circuit 90 can include a substrate 92 and an aperture 94 on the substrate 92. A dam can also be useful in this scenario to prevent spillage of over-mold material or other conformal coating through the aperture 94. Referring to FIG. 10, solder 96 can be applied around the periphery of the aperture 94 (presumably over a printed trace) to form a dam that prevents spillage of over-mold 95 through the aperture 94. Thus, as the previous examples illustrate, the conformal coating can be applied “about” the dam, either within the dam or outside the dam. A conformal coating can also be applied to a predetermined area where no components lie underneath. as shown in examples of FIGS. 9 and 10.

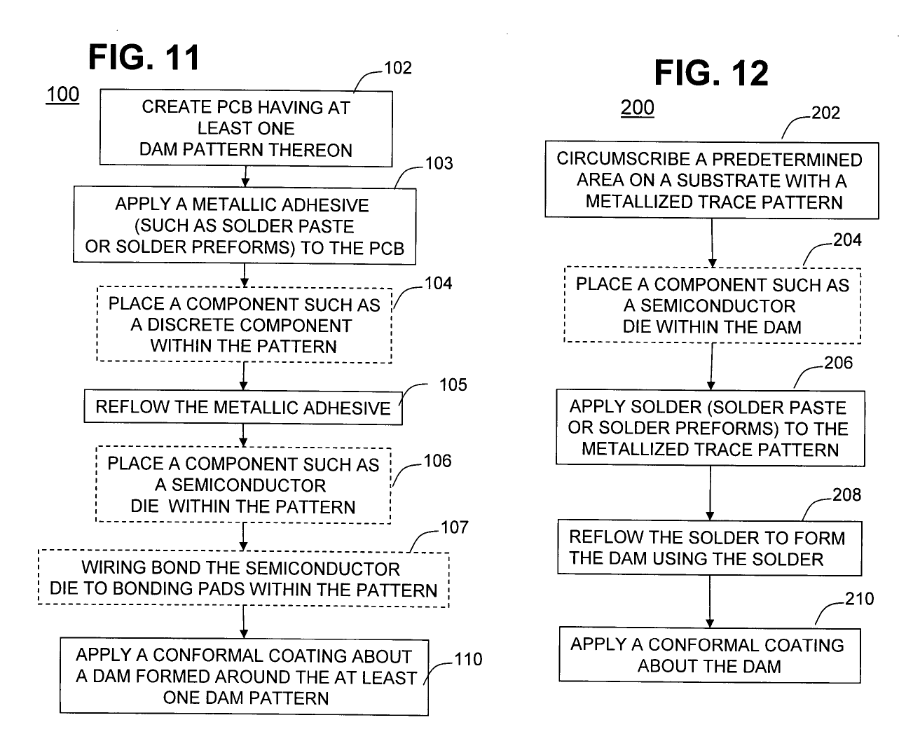

Referring to FIG. 11, a method 100 of forming a metallized dam can include the steps of creating a PCB having at least one dam pattern at step 10, applying a metallic adhesive to the at least one dam pattern on the PCB at step 103, and applying a conformal coating about a dam formed around the dam pattern at step 110. The metallic adhesive can be solder such as solder paste or solder preforms. The step of applying the metallic adhesive can include reflowing the solder paste or the solder preforms on to the at least one dam pattern at step 105. The method can also include the optional steps of placing a component either before or after the reflow step 105. For example, a discrete component can be placed within the dam at step 104. In another example, a semiconductor die can be placed within the dam at step 106 after the reflow step 105 and wire bonded to bonding pads within the dam at step 107 before the step of applying the conformal coating at step 110. Note again that the application of solder paste or even preforms can be adjusted to provide a customized height for the dam.

Referring to FIG. 12, a method 200 of forming a dam can include the steps of circumscribing at step 202 a predetermined area on a substrate with a metallized trace pattern, applying solder at step 206 such as solder paste or solder preforms to the metallized trace pattern, and reflowing the solder at step 208 to form the dam using the solder. The method can further include the steps of optionally placing a semiconductor die within the dam at step 204 and applying a conformal coating about the dam at step 210.

Thus, the embodiments in accordance with the invention solves among other problems, the problem of insufficient clearance with other components. While the preferred embodiments of the invention have been illustrated and described, it will be clear that the invention is not so limited. For example, both pre-form and solder paste can be used to create a particular dam instead of just solder paste or pre-form only. Numerous modifications, changes, variations, substitutions and equivalents will occur to those skilled in the art without departing from the spirit and scope of the present invention as defined by the appended claims.

Additionally, the description above is intended by way of example only and is not intended to limit the present invention in any way, except as set forth in the following claims.

1. An method of forming a metallized dam, comprising the steps of:
applying a metallic adhesive to a printed circuit board having at least one dam pattern thereon; and
applying a conformal coating about a dam formed around the at least one dam pattern.

2. The method of claim 1, wherein the step of applying the metallic adhesive comprises the step of applying solder paste to the at least one dam pattern.

3. The method claim 2, wherein the step of applying the metallic adhesive further comprises the step of reflowing the solder paste onto the at least one dam pattern,

4. The method of claim 1, wherein the step of applying the metallic adhesive comprises the step of applying solder preform to the at least one dam pattern.

5. The method claim 4, wherein the step of applying the metallic adhesive further comprises the step of reflowing the solder preform on to the at least one dam pattern.

6. The method of claim 1, wherein the method further comprises the step of placing a semiconductor die within the dam before the step of applying the conformal coating.

7. The method of claim 6, wherein the method further comprises the step of wiring bonding the semiconductor die to bonding pads within the dam before the step of applying the conformal coating.

8. The method of claim 1, wherein the step of applying the metallic adhesive comprises the step of screen printing solder paste onto the at least one dam pattern.

9. The method of claim 8, wherein the at least one dan pattern is electrically non-functional and the step of screen printing is adjustable to provide a customized height for the dam.

10. The method of claim 1, wherein the dam has a clearance requirement of less than 47 mils.

11. The method of claim 1, wherein the step of applying a conformal coating about the dam comprises at least one among applying the conformal coating within the dam and applying the conformal coating around the dam.

12. A method of forming a dam, comprising the steps of:
circumscribing a predetermined area on a substrate with a metallized trace pattern;
applying solder to the metallized trace pattern; and
reflowing the solder to form the dam using the solder.

13. The method of claim 12, wherein the step of applying solder comprises the step of applying solder paste to the metallized trace pattern.

14. The method of claim 12, wherein the step of applying the solder comprises the step of applying solder preform to the metallized trace pattern.

15. The method of claim 12, wherein the method further comprises the step of applying a conformal coating about the dam.

16. The method of claim 12, wherein the method further comprises the step of placing a semiconductor die within the dam.

17. (canceled)

18. (canceled)

19. (canceled)

20. (canceled)

21. An method of forming a metallized dam, comprising the steps of:
applying a metallic adhesive to a printed circuit board having at least one dam pattern thereon; and
forming the metallized dam on the at least one dam pattern using the metallic adhesive.

22. The method of claim 21, wherein the method further comprises the step of applying a conformal coating about the metallized dam.

23. The method of claim 21, wherein the step of applying the metallic adhesive comprises the step of applying solder paste to the at least one dam pattern.

24. The method of claim 22, wherein the method further comprises the step of placing a semiconductor die within the metallized dam before the step of applying the conformal coating.
